(19) United States
(12) Patent Application Publication
(10) Pub. No.: US 2025/0338558 A1
(43) Pub. Date: Oct. 30, 2025

(54) INTEGRATED CIRCUIT WITH ION IMPLANTATION IN ILD

(71) Applicant: Taiwan Semiconductor Manufacturing Co., Ltd., Hsinchu (TW)

(72) Inventors: Shi-Sheng HU, Hsinchu (TW); Tsung-Hung LEE, Hsinchu (TW); Chien-Tai CHAN, Hsinchu (TW); Huiling SHANG, Hsinchu (TW)

(21) Appl. No.: 18/920,665

(22) Filed: Oct. 18, 2024

Related U.S. Application Data
(60) Provisional application No. 63/638,849, filed on Apr. 25, 2024.

(51) Int. Cl. H01L 29/423; H01L 21/8234; H01L 27/088; H01L 29/06; H01L 29/08; H01L 29/167; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 62/834; H10D 84/0128; H10D 84/013; H10D 84/038; H10D 84/83

(57) ABSTRACT

An integrated circuit includes an interlevel dielectric layer having a first portion directly above a source/drain region of a transistor and a second portion directly above the source/drain region and laterally abutting the first portion. The first and second portions have different material compositions such that that the interlevel dielectric region imparts a beneficial strain to the transistor.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A-1O are cross-sectional views of an integrated circuit at various stages of processing, in accordance with some embodiments.

FIG. 2A-2D are cross-sectional views of an integrated circuit at various stages of processing, in accordance with some embodiments.

FIG. 3A-3E are cross-sectional views of an integrated circuit at various stages of processing, in accordance with some embodiments.

FIG. 4 is a cross-sectional view of an integrated circuit, in accordance with some embodiments.

FIGS. 5A and 5B are perspective and cross-sectional views of an integrated circuit, in accordance with some embodiments.

FIG. 6 is a top view of an integrated circuit layout, in accordance with some embodiments.

FIG. 7 is a top view of an integrated circuit layout, in accordance with some embodiments.

FIG. 8 is a top view of an integrated circuit layout, in accordance with some embodiments.

FIG. 9A is a graph illustrating dopant concentration versus the depth of the interlevel dielectric layer, in accordance with some embodiments.

FIG. 9B is a graph illustrating implantation damage in the interlevel dielectric layer 146 versus the depth of the interlevel dielectric layer, in accordance with some embodiments.

FIG. 10 is a flow diagram of a method of manufacturing an integrated circuit, in accordance with some embodiments.

FIG. 11 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets). The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the disclosure provide an integrated circuit including an interlevel dielectric layer formed above a source/drain region of a transistor. During processing, the interlevel dielectric layer is altered so that a first portion of the interlevel dielectric layer has a first composition and a second portion of the interlevel dielectric layer has a second composition different from the first composition. In some embodiments, the difference in composition is accomplished by patterning a mask above the interlevel dielectric layer such that the first portion of the interlevel dielectric layer is covered by the mask while the second portion of the interlevel dielectric layer is exposed by the mask. In some embodiments, an ion implantation process is then performed to change the composition of the exposed second portion of the interlevel dielectric layer. In some embodiments, the second portion of the interlevel dielectric layer is removed and replaced with a dielectric material that is different than the remaining dielectric material of the first portion of the interlevel dielectric layer. This difference in composition imparts a beneficial strain to the source/drain region of the transistor. This results in improved performance of the transistor, for example by improving the mobility of charge carriers in the source/drain region. Furthermore, undesired oxygen concentrations in both N-type and P-type regions can be reduced, resulting in improvement in both N-type and P-type transistors. Additionally, the capacitance equivalent thickness is also reduced.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

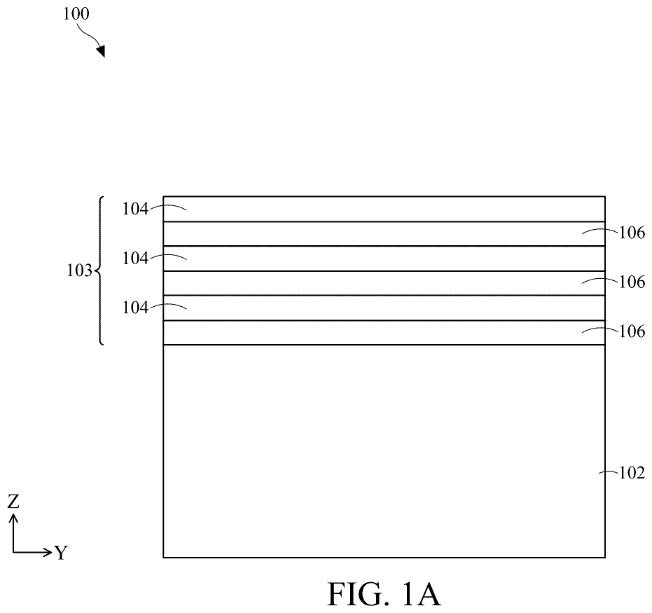

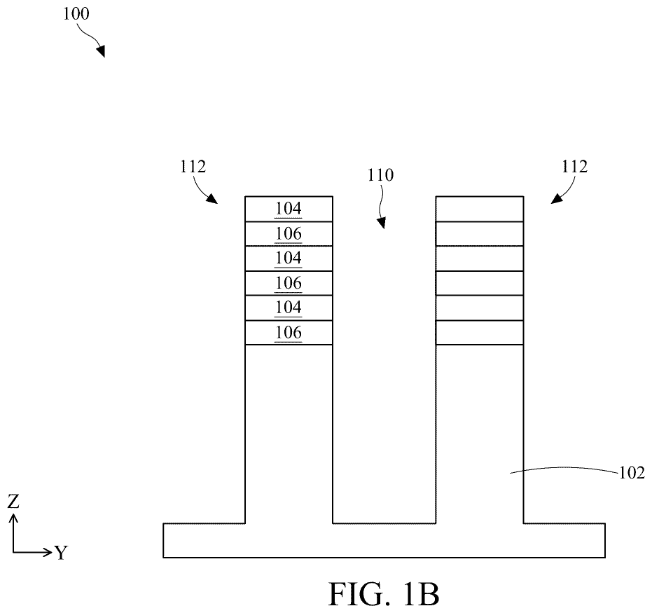

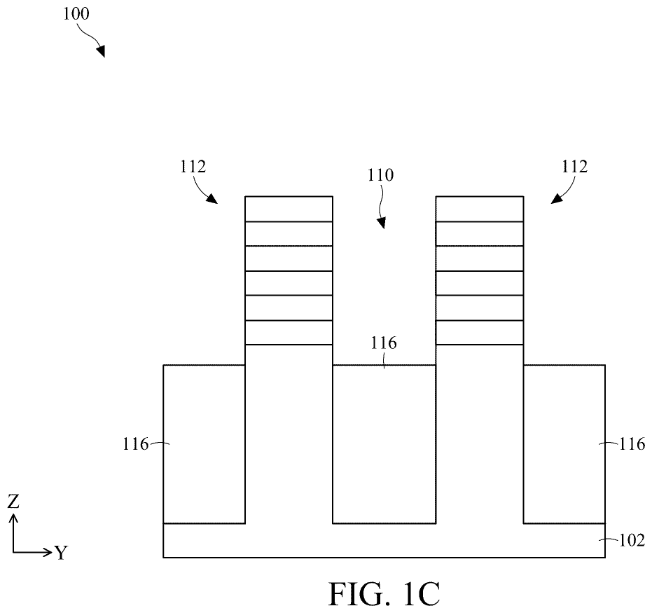

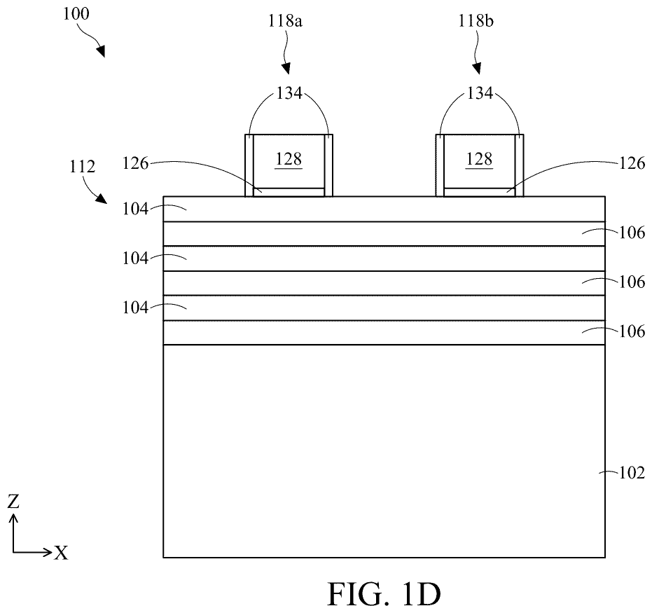

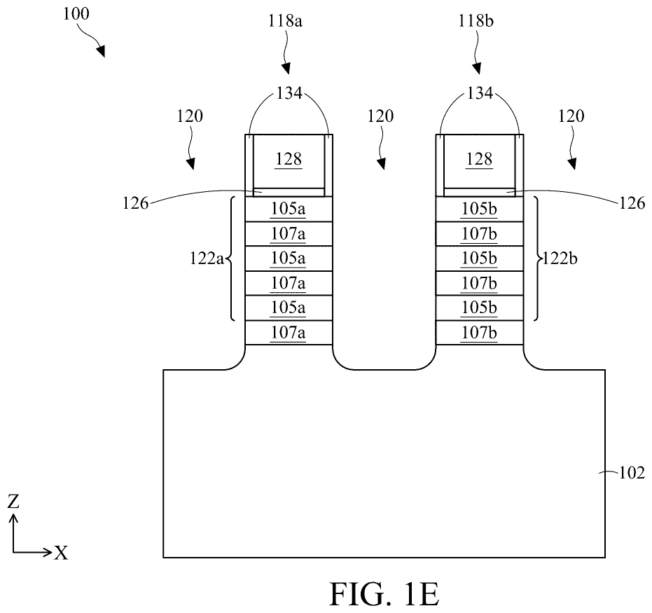

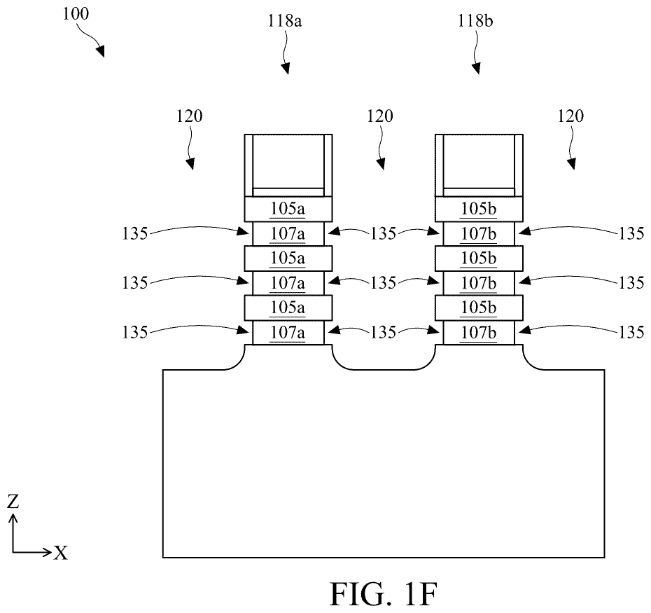

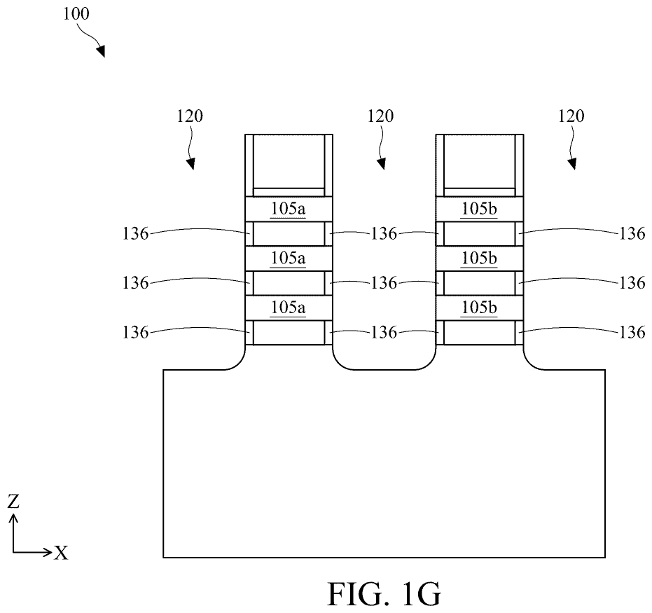

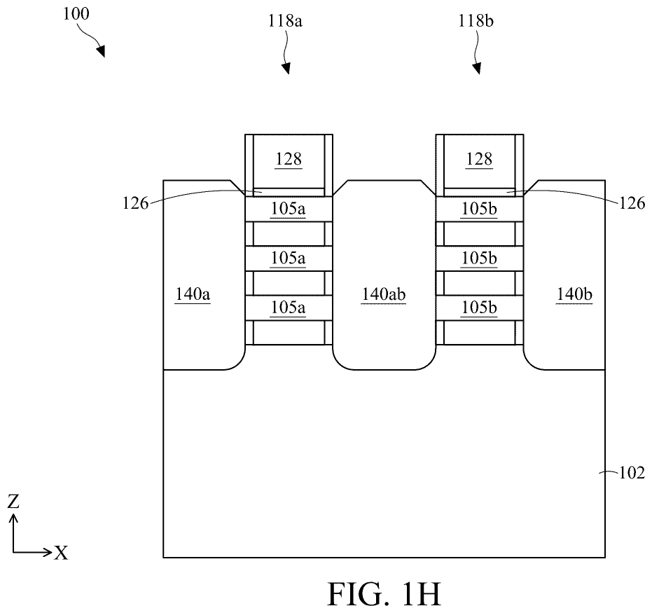

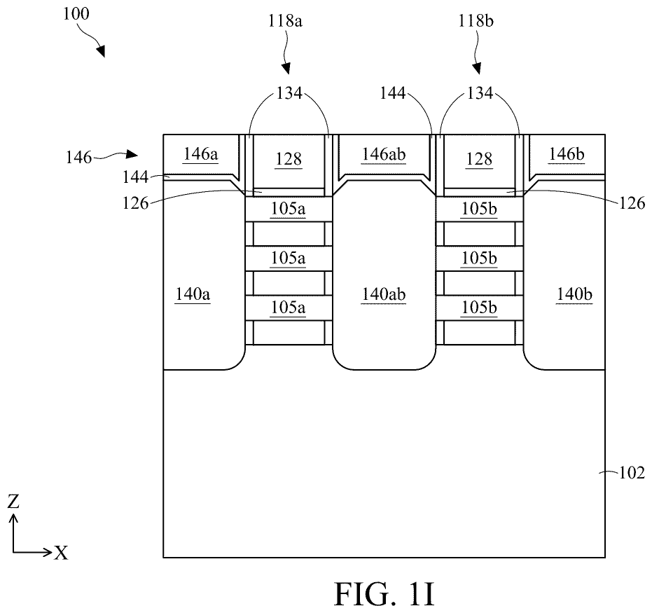

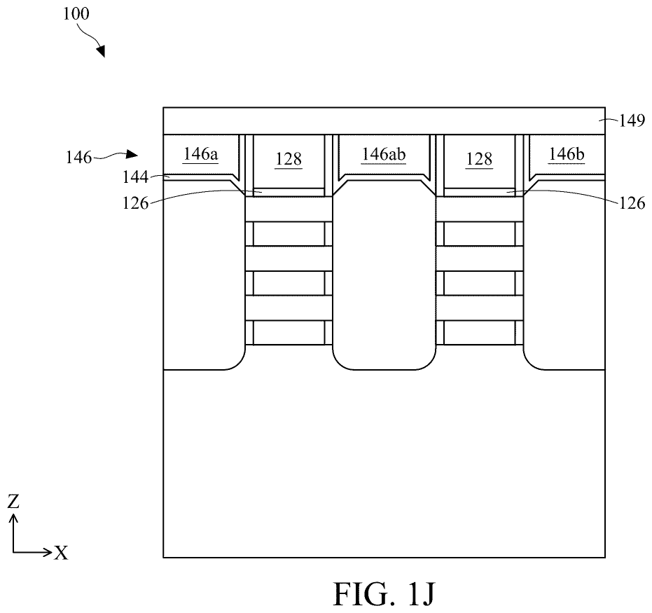

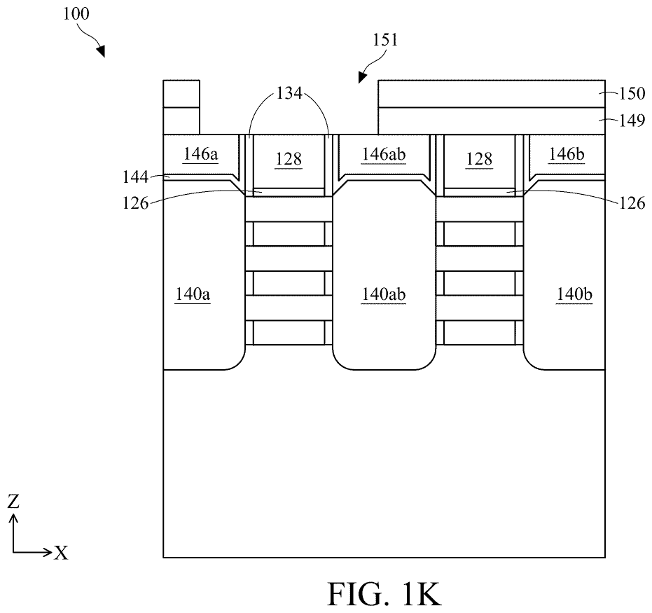

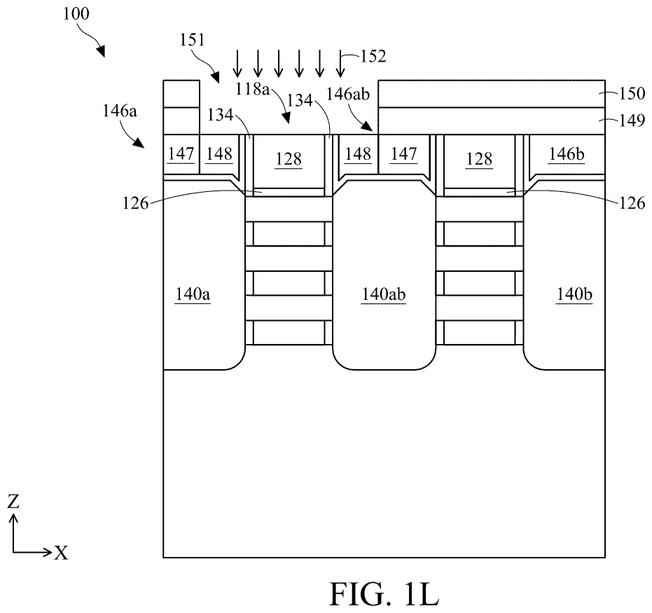

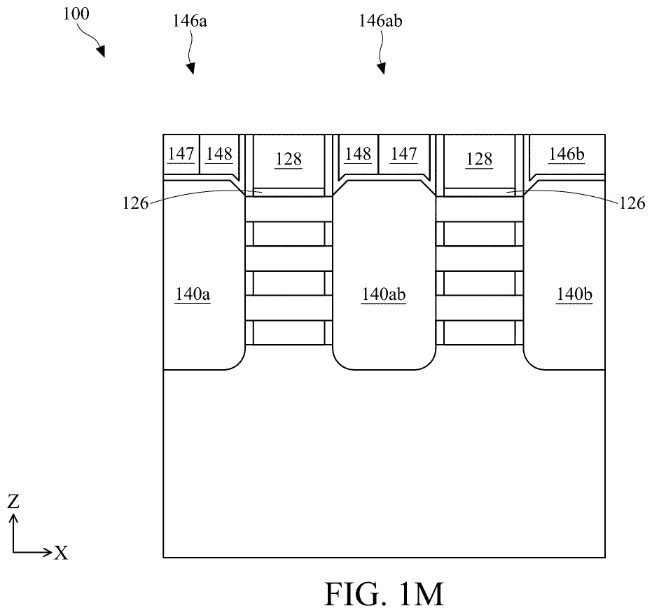

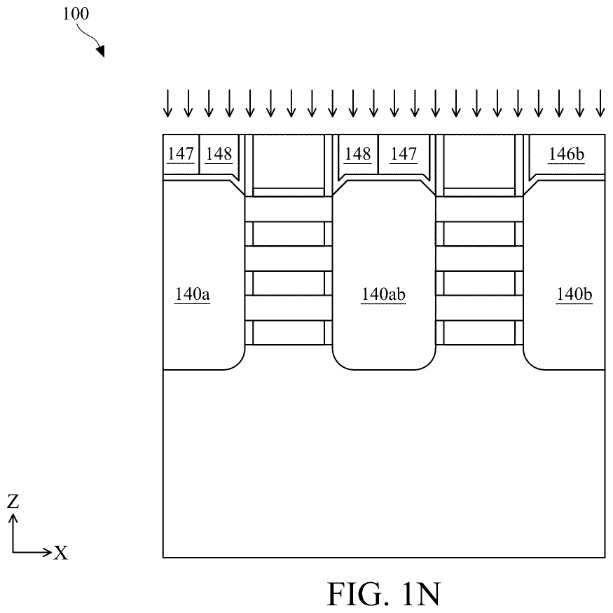

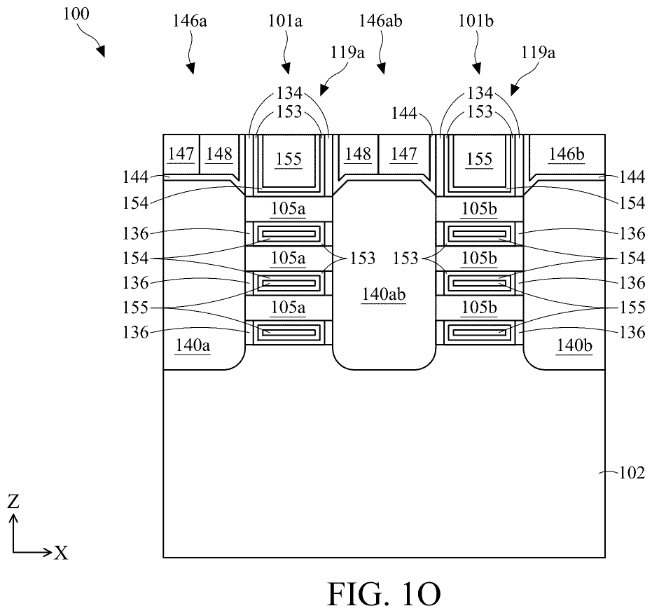

FIGS. 1A-1O are cross-sectional views of an integrated circuit 100 fabricated in accordance with some embodiments of the present disclosure. The fabrication process results in a plurality of transistors 101, as will be described in further detail below.

FIG. 1A is a cross-sectional view of the integrated circuit 100 at an intermediate state of processing. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In FIG. 1, Three semiconductor layers 104 and three sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

In FIG. 1B, trenches 110 have been formed in the stack 103 and in the substrate 102. Though not shown in FIG. 1B, a hard mask layer is first formed and patterned on the stack 103. The trenches 110 can be formed with an anisotropic etching process that etches in the downward direction in the presence of the patterned hard mask. The etching process defines semiconductor fins 112 by forming trenches 110 through the sacrificial semiconductor layers 106, the semiconductor layers 104, and the substrate 102.

FIG. 1C is a cross-sectional Y-view, in accordance with some embodiments. In FIG. 1C, shallow trench isolation regions 116 have been formed by depositing a dielectric material in the trenches 110 between fins 112. The shell dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure. After deposition of the dielectric material, an etch-back process has been performed to recess the top of the shallow trench isolation regions 116 below the lowest sacrificial semiconductor layers 106.

FIG. 1D is an X-view of the integrated circuit 100, in accordance with some embodiments. In FIG. 1D, sacrificial gate structures 118a and 118b have been formed over the fins 112. In the figures, some reference numbers may include a suffix “a”, “b”, or “ab”. The suffixes may be included when reference is made to a particular structure. However, in various cases the description may omit the suffixes when description applies generally to the structure of that reference number. For example, when an aspect of description is not particular to the sacrificial gate structure 118a or 118b, but is general to both sacrificial gate structures, the suffix “a” and “b” and reference may be made simply to the sacrificial gate structures 118.

The sacrificial gate structures 118 extend in the Y direction, perpendicular to the fins 112. In practice, each sacrificial gate structure 118 crosses multiple fins 112. The sacrificial gate structures 118 are also formed in the trenches 110.

The sacrificial gate structures 118 include a dielectric layer 126. In an exemplary embodiment, the dielectric layer 126 includes silicon oxide. However, alternatively, the dielectric layer 126 can include SiN, SiCN, SiOC, SiOCN, or other dielectric materials without departing from the scope of the present disclosure. In some embodiments, the dielectric layer 126 has a low K dielectric material. The dielectric layer 126 can be deposited by CVD, ALD, or PVD.

The sacrificial gate structures include a sacrificial gate layer 128 on the dielectric layer 126. The sacrificial gate layer 128 can include materials that have a high etch selectivity with respect to the trench isolation regions 116. In an exemplary embodiment, sacrificial gate layer 128 includes polysilicon. However, the sacrificial gate layer 128 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 128 may be deposited by physical vapor deposition (PVD), CVD, sputter deposition, or other techniques for depositing the selected material. Though not shown in FIG. 1D, in some embodiments, the sacrificial gate structures 118 may include additional dielectric layers above the sacrificial gate layer 128.

Gate spacer layers 134 have been formed on the sidewalls of the sacrificial gate structures 118. In particular, the gate spacer layers 134 may be formed on sidewalls of the dielectric layer 126 and the sacrificial gate layer 128. The gate spacer layers 134 may also be formed on other exposed surfaces of the integrated circuit. The gate spacer layer 134 can be formed by PVD, CVD, ALD, or other suitable deposition processes. Following formation of the gate spacer layer 134, horizontal portions (e.g., in the X-Y plane) of the gate spacer layer 134 may be removed by an anisotropic etching process, thereby exposing upper surfaces of the fins 112 and the dielectric layer 134. After patterning of the gate spacer layers, vertically thicker portions of the gate spacer layers 134 may remain. The gate spacer layers 134 can include one or more of SiO, SiN, SiON, SiCN, SIOCN, SiOC, or other suitable dielectric materials.

In FIG. 1E, source/drain trenches 120 have been formed, in accordance with some embodiments. After patterning of the gate spacer layers 134, one or more etching processes are performed to form the source/drain trenches 120 in the fins 112. Forming the source/drain trenches 120 includes etching through each of the semiconductor layers 104 and sacrificial semiconductor layers 106, and a portion of the substrate 102. Accordingly, the removal operations may include suitable etch operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 120 results in formation of stacks 122 of channels 105. In particular, the portions of the semiconductor layers 104 after formation of the source/drain trenches 120 now correspond to channels of a transistor. Formation of the source/drain trenches 120 also results in formation of a plurality of sacrificial semiconductor nanostructures 107 from the sacrificial semiconductor layers 106.

FIG. 1E illustrates a stack 122a of channels 105a interleaved with sacrificial semiconductor nanostructures 107a below the sacrificial gate structure 118a. FIG. 1E also illustrates a stack 122b of channels 105b interleaved with sacrificial semiconductor nanostructures 107b below the sacrificial gate structure 118a. In practice, a large number of source/drain trenches 120 are formed in the fins 112. A stack 122 of channels 105 is positioned between each source/drain layer. Each stack 122 of channels 105 corresponds to the stacked channels 105 of a transistor. For example, the stack 122a of channels 105a will correspond to channels of a transistor 101a. The stack 122b of channels 105b will correspond to channels of a transistor 101b.

In FIG. 1F, a selective etching process is performed to recess exposed end portions of the sacrificial semiconductor nanostructures 107 without substantially etching the sacrificial semiconductor nanostructures 107. More particularly, recesses 135 are formed in the sacrificial semiconductor nanostructures 107 between adjacent channels 105, or between the lowest channel 105 and the substrate 102. The recesses 135 can be formed by performing an etching process that selectively etches the material of the sacrificial semiconductor nanostructures with respect to the material of the channels 105 and the substrate 102.

In FIG. 1G, inner spacers 136 have been formed in the recesses 135, in accordance with some embodiments. The inner spacers 136 are formed by depositing a dielectric material to fill the recesses 135 between the channels 105. Deposition of the dielectric material for the inner spacers 136 may also partially or completely fill the source/drain trenches 120. An etching process, such as an anisotropic etching process, is performed to remove portions of the dielectric material disposed outside the recesses 135. The remaining portions of the dielectric material correspond to the inner spacers 136 shown in FIG. 1G. The inner spacer 136 may be a suitable dielectric material, such as silicon carbon nitride (SiCN), silicon oxycarbonitride (SiOCN), or the like, formed by a suitable deposition method such as physical vapor deposition (PVD), CVD, ALD, or the like.

In FIG. 1H, source/drain regions 140 have been formed, in accordance with some embodiments. The source/drain regions 140 are epitaxially grown from the channels 105. The source/drain regions 140 are grown on exposed portions of the fins 112 and contact the channels 105. For each stack 122 of channels 105, there are two source/drain regions 140. Some stacks 122 of channels 105 may share a source/drain 140 with a stack 122 of channels 105 that is adjacent in the X direction.

In FIG. 1H, a source/drain region 140a is formed on the left of the channels 105a and is in contact with left ends of the channels 105a. A second source/drain region 140ab is formed between the channels 105a and the channels 105b. The source/drain region 140ab is in contact with right ends of the channels 105a and left ends of the channels 105b. Accordingly, the source/drain region 140ab is a shared source/drain region of the transistors 101a and 101b. A source/drain region 140b is in contact with right ends of the channels 105b. The The source/drain regions 140 may include any acceptable material, such as appropriate for N-type or P-type devices. For N-type devices, the source/drain regions 140 include materials exerting a tensile strain in the channel regions, such as silicon, SiC, SiCP, SiP, or the like, in some embodiments. When P-type devices are formed, the source/drain regions 140 include materials exerting a compressive strain in the channel regions, such as SiGe, SiGeB, Ge, GeSn, or the like, in accordance with certain embodiments. The source/drain regions 140 may have surfaces raised from respective surfaces of the fins and may have facets. Neighboring source/drain regions 140 may merge in some embodiments to form a singular source/drain region 140 over two neighboring fins of the fins 112.

The source/drain regions 140 may be implanted with dopants followed by an annealing process. The source/drain regions 140 may have an impurity concentration of between about 10¹⁹ cm⁻³ and about 10²¹ cm⁻³. N-type and/or P-type impurities for source/drain regions 140 may be any of the impurities previously discussed. In some embodiments, the source/drain regions 140 are in situ doped during growth.

In FIG. 1I, a contact etch stop layer (CESL) 144 and an interlayer dielectric (ILD) 146 have been formed, in accordance with some embodiments. The CESL layer 144 can include a thin dielectric layer conformally deposited on exposed surfaces of the source/drain regions 140, the gate spacer layers 134, and on other exposed surfaces. The CESL layer 144 can include SiN, SiC, SiOC, SiOCN, SiON, or other suitable dielectric materials. The CESL 144 can be deposited by CVD, ALD, PVD, or other suitable deposition processes.

The interlevel dielectric layer 146 covers the CESL 144. The interlevel dielectric layer 146 fills the remaining spaces between adjacent sacrificial gate structures 118. Interlevel dielectric layer may correspond to a lowest interlevel dielectric layer of the integrated circuit 100. In some embodiments, the interlevel dielectric layer 146 may be termed ILDO. Though not shown herein, additional interlevel dielectric layers may be formed over the interlevel dielectric layer 146. A network of conductive vias and metal lines may be formed in the upper interlevel dielectric layers. The interlevel dielectric layer 146 can include SiO, SiON, SiN, SiC, SiOC, SiOCN, SiON, or other suitable dielectric materials. The interlevel dielectric layer 146 can be deposited by CVD, ALD, PVD, or other suitable deposition processes. At the stage of processing shown in FIG. 1I, the interlevel dielectric layer 146 includes an interlevel dielectric region 146a above the source/drain region 140a, a second interlevel dielectric region 146ab above the source/drain region 140ab, and a third interlevel dielectric region 146b above the source/drain region 140b.

In some embodiments, CMP process is performed after deposition of the interlevel dielectric layer 146. The result of the CMP process is that the top surfaces of the interlevel dielectric layer 146, the CESL layer 144, the gate spacer layer 134, and the sacrificial gate layer 128 are coplanar. The CMP process may also reduce the height of the sacrificial gate structures 118.

In FIG. 1J, a hard mask layer 149 has been deposited on the integrated circuit 100, in accordance with some embodiments. The hard mask layer 149 is deposited on the top surfaces of the CESL layer 144, the interlevel dielectric layer 146, the gate spacer layer 134, and the sacrificial gate layers 128. In an exemplary embodiment, the hard mask layer includes SiN. Alternatively, the hard mask layer 149 can include SiON, SiC, SiOC, SiOCN, SiON, or other suitable dielectric materials. The interlevel dielectric layer 146 can be deposited by CVD, ALD, PVD, or other suitable deposition processes.

In FIG. 1K, a layer of photoresist 150 has been deposited on the hard mask layer 149, in accordance with some embodiments. After deposition of the layer of photoresist 150, a photolithography processes been performed to form openings 151 in the layer of photoresist 150 and the hard mask layer 149. Accordingly, the hard mask layer 149 has been patterned to expose selected regions of the interlevel dielectric layer 146. In particular, for the interlevel dielectric layer has regions 146a and 146ab above the source/drain region 140a and 140ab, a first portion of each of the regions 146a and 146ab is covered, while a second portion of each of the regions 146a and 146ab layer is exposed. The interlevel dielectric layer region 146b above the source/drain region 140b is entirely covered by the hard mask layer 149.

In FIG. 1L, an ion implantation processes been performed, in accordance with some embodiments. During the ion in implantation process, the integrated circuit 100 is bombarded with high-energy dopant species 152. The areas of the integrated circuit 100 covered by the hard mask layer 149 are shielded from the dopant species 152, such that the dopant species 152 do not enter into the covered portions of the integrated circuit 100. The dopant species 152 are driven into the exposed areas of the integrated circuit 100. In particular, the dopant species are driven into the exposed portions of the regions 146a and 146ab, and to the exposed portions of the sidewall spacers 134, into the exposed portions of the CESL layer 144, and then to the exposed portions of the sacrificial gate layer 128 of the sacrificial gate structure 118a.

In some embodiments, the dopant species 152 include dopant atoms or dopant molecules. The dopant atoms or molecules can be ionized. In some embodiments, the dopant species 152 and include nitrogen, helium, silicon, germanium, argon, or other suitable particles. The depth to which the dopant species are implanted in the interlevel dielectric layer 146 is based, in part, on the kinetic energy of the dopant species and on the type of the dopant species. In some embodiments, the dopant species have energies between 1 keV and 6 keV. In one exemplary embodiment, the dopant species include nitrogen between 1 keV and 3 keV, resulting in high concentrations of dopants in the exposed portions of the interlevel dielectric layer 146 to depths between 0 nm and 25 nm. In one exemplary embodiment, the dopant species 152 include germanium with energies between 2 keV and 4 keV, resulting in high concentrations of dopants in the exposed portions of the interlevel dielectric layer 146 to depths between 0 nm and 20 nm. Other dopant species, energies, and implantation depths can be utilized without departing from the scope of the present disclosure. In some embodiments, the dopant concentrations are between 1E18 atoms/cm\hat{ }3 and 5E21 atoms/cm\hat{ }3, though other concentrations can be utilized without departing from the scope of the present disclosure.

After the dopant implantation processes been performed, the interlevel dielectric layer region 146a and the interlevel dielectric layer region 146ab are each divided into two portions having different material compositions. In particular, the interlevel dielectric layers 146a and 146ab each include a first portion 147 and a second portion 148 having different material compositions. The first portion 147 includes the original material of the interlevel dielectric layer 146, substantially unchanged. In an exemplary embodiment, the first portion 147 includes silicon oxide. The second portion 148 includes silicon oxide with high concentrations of the dopant species 152. Accordingly, in examples in which the dopant species are nitrogen or germanium, the second portion 148 includes SiON or SiGcO.

In some embodiments, a global dopant implantation process is performed prior to formation of the mask layer 149. In some embodiments, the global implantation process uses a first type of dopant species. Afterwards, the dopant implantation process of FIG. 1L (partial dopant implantation process) can be performed in the presence of the mask and can implant a second dopant species, different than the first dopant species, thereby causing the portions 148 to have a different material composition than the portions 147. In some embodiments, the first dopant species is N2 and the second dopant species is Ge, though other combinations of species can be utilized without departing from the scope of the present disclosure. In some embodiments, only PFET regions receive the global implantation process. In some embodiments, only NFET regions receive the global implantation process. In some embodiments, only PFET regions receive the partial implantation process. In some embodiments, only NFET regions receive the partial implantation process. In some embodiments, only certain types of devices (logic transistors, I/O transistors, bipolar junction transistors, electrostatic discharge protection transistors, or SRAM transistors, etc.) receive the partial implantation process while other types of devices do not.

In FIG. 1M, the hard mask layer 149 and the photoresist layer 150 have been removed, in accordance with some embodiments. Accordingly, the entire surface of the integrated circuit 100 is now exposed without a mask coverage. As can be seen in FIG. 1M, the regions 146a and 146ab include portions 147 and 148 having different material compositions, while the region 146b has a uniform material composition corresponding to the material composition of the initial deposition of the interlevel dielectric layer 146.

In FIG. 1N, a thermal annealing process has been performed, in accordance with some embodiments. The thermal annealing process can correspond to a rapid thermal annealing process with peak temperatures between 1100° C. and 1300° C. In an exemplary embodiment, the thermal annealing process has a peak temperature between 1140° C. and 1160° C. In some embodiments, to avoid damaging the source/drain regions 140, the annealing temperature is selected to be less than or equal to the processing temperature for forming the source/drain regions 140. In some embodiments, the annealing process has a temperature between 1050° C.-1150° C. Other temperatures can be utilized without departing from the scope of the present disclosure. In some embodiments, the thermal annealing process is a microsecond annealing process having a duration between 1 ms and 2 ms. Other temperatures and durations can be utilized for the annealing process without departing from the scope of the present disclosure.

In some embodiments, after the thermal annealing process, the difference in materials between the portions 147 and 148 results in a strain being imparted to the source/drain regions 140a and 140ab. In some embodiments, the source/drain regions 140a and 140ab are P-type source/drain regions. The portions 147 and 148 impart a tensile strain in the source/drain regions 140a and 140ab and in the channels 105a and 105b. This results in increased mobility of holes (P-type charge carriers) in the corresponding P-type transistors. This further results in improved current performance in the lady region and the saturation region of the P-type transistors. Furthermore, undesired oxygen concentrations in both N-type and P-type regions can be reduced, resulting in improvement in both N-type and P-type transistors. Additionally, the capacitance equivalent thickness is also reduced for both N-type and P-type transistors.

In FIG. 1O, the channels 105 are released by removal of the sacrificial semiconductor nanostructures 107. The sacrificial semiconductor nanostructures 107 can be removed by a selective etching process using an etchant that is selective to the material of the sacrificial semiconductor nanostructures 107, such that the sacrificial semiconductor nanostructures 107 are removed without substantially etching the channels 105. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial semiconductor nanostructures 107 are removed and the channels 105 are patterned to form channel regions of both PFETs and NFETs. Removal of the sacrificial semiconductor nanostructures 107 results in the formation of voids between the channels 105.

In FIG. 1O, a gate dielectric layer 153 has been deposited on exposed portions of the channels 105 and sidewall spacers 134, in accordance with some embodiments. While FIG. 1O illustrates a single gate dielectric layer 153, in practice, the gate dielectric layer 153 includes an interfacial gate dielectric layer and a high-K gate dielectric layer. The interfacial gate dielectric layer forms directly on the exposed portions of the channels 105. The high-K gate dielectric layer forms on the interfacial gate dielectric layer and on other exposed surfaces, such as the exposed sidewalls of the gate spacer layers 134.

The interfacial gate dielectric layer is wrapped around the channels 105. The interfacial gate dielectric layer can include a dielectric material such as silicon oxide, silicon nitride, or other suitable dielectric materials. The interfacial gate dielectric layer can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer can be formed by a thermal oxidation process, a chemical vapor deposition (CVD) process, or an atomic layer deposition (ALD) process. The interfacial gate dielectric layer can have a thickness between 0.5 nm and 2 nm. Other materials, deposition processes, and thicknesses can be utilized for the interfacial gate dielectric layer without departing from the scope of the present disclosure.

The high-K gate dielectric layer is deposited in a conformal deposition process. The conformal deposition process deposits the high-K gate dielectric layer on the interfacial gate dielectric layer, on the substrate 102, on the trench isolation regions 116, and on the gate spacer layers 134. The high-K gate dielectric layer is wrapped around the channels 105. The high-K gate dielectric layer has a thickness between 1 nm and 3 nm. The high-K dielectric layer includes one or more layers of a dielectric material, such as HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer may be formed by CVD, ALD, or any suitable method. Other thicknesses, deposition processes, and materials can be utilized for the high-K gate dielectric layer without departing from the scope of the present disclosure.

In FIG. 1O, a gate metal 154 and a gate metal 155 have been deposited. The gate metal 154 is deposited on all exposed surfaces of the high-K gate dielectric layer. The gate metal 155 is deposited on the gate metal 154. The gate metal 155 may correspond to a gate fill material that fills all remaining space previously occupied by the sacrificial gate layer 128 and the sacrificial semiconductor nanostructures 107. The gate metals 154 and 155 are wrapped around the channels 105. In some embodiments, the gate metal 154 corresponds to a work function layer selected to impart a particular threshold voltage to the corresponding transistors. The work function layer 154 can include titanium nitride, tantalum nitride, or other suitable conductive materials. The gate metal 155 can include one or more of Ti, TiN, Ta, TaN, Al, Cu, Co, Ru, W, Au, or other suitable conductive materials. The gate metals 154 and 155 can be deposited by PVD, ALD, or CVD. Other configurations, materials, and deposition processes can be utilized for the gate metal 155 without departing from the scope of the present disclosure. The gate metal 155 acts as a gate electrode surrounding the channels 105. In some embodiments, only a single gate metal is utilized. In some embodiments, more than two gate metals are utilized. In practice, the gate metals can include one or more conductive liner layers, work function layers, and gate fill layers that collectively make up the gate metal. The gate metals 154 and 155 correspond to a gate electrode of the corresponding transistors.

At the stage of processing shown in FIG. 1O, the transistors 101 are substantially complete. Each transistor 101 includes a stack 122 of channels 105 extending between the source/drain regions 140 and acting as stacked channels of the transistor 101. In particular, the transistor 101a includes the channels 105a extending between the source/drain regions 140a and 140ab. The transistor 101b includes the channels 105b extending between source/drain regions 140ab and 140b. The transistor includes a gate structure 119a including at least the gate metal 155. The transistor 101a benefits from the effects of the regions 146a and 146ab having the portions 147 and 148 having different material compositions, as described above. The transistor 101b includes a gate structure 119b including at least the gate metal 155. The transistor 101b benefits from the portions 147 and 148 of the region 146ab. The transistor 101b includes the source/drain region 140b that does not receive the effects of different material compositions of the interlevel dielectric layer because the region 146b does not have separate regions of different composition. Though not shown in FIG. 1O, source/drain contact may also be formed in contact with the source/drain regions 140 offset the Y direction such that the portions 147 and 148 still remain above the source/drain regions 140a and 140ab. A silicide may be formed with a source/drain contact metal formed on top of the silicide. In some embodiments, the source/drain contact passes through both the portions 147 and 148. In some embodiments, the source/drain contact contacts both the portions 147 and 148.

In some embodiments, the silicide is formed is formed by patterning the interlevel dielectric layer 146 to expose a portion of the corresponding source/drain layer 140 and depositing a thin metal layer on the exposed portion of the source/drain layer 140. The opening can be formed at a location offset in the Y-direction relative to the view of FIG. 1O. In some embodiments, the opening extends through one or both of the portions 147/148 to contact the source/drain layer. After depositing the thin metal layer, a thermal annealing process can be performed to form the silicide from the material of the thin metal layer and the source/drain region 140. In some embodiments, silicide will include composition from one or more of the portions 147 and 148, depending on the locations of the opening. The source/drain contact is then formed in the opening by depositing a metal in the opening on the silicide.

In some embodiments, the shape of the source/drain contact is affected by the portions 147/148. For example, an etching process to exposed the source/drain region 140 can selectively etch one portion 147/148 relative to the other. Accordingly, the contact may be formed through only one of the portion 147/148. Alternatively, in some embodiments the contact is formed through both the portions 147/148.

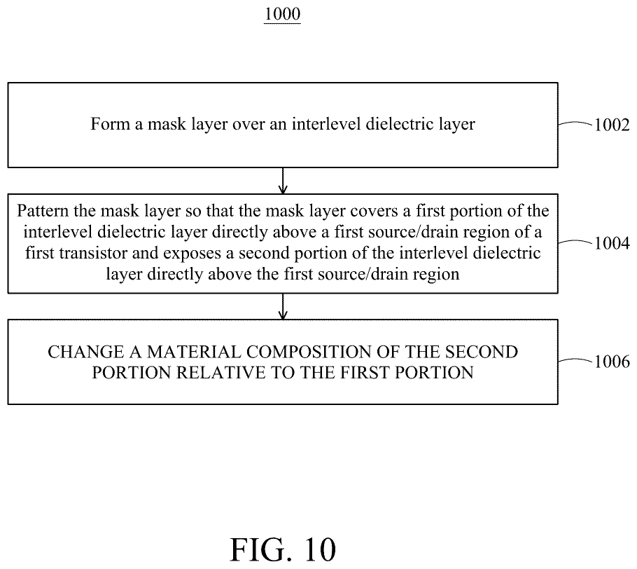

Although FIGS. 1A-10 how described the process in which the portions 147 and 148 have been formed prior to formation of the gate metal 155, in practice, the portions 147 and 148 can be formed after formation of the gate metal 155. In particular, after formation of the gate metal 155, the hard mask layer 149 of the photoresist layer 150 can be deposited and patterned and the dopant implantation process in thermal annealing process can be performed as described in relation to FIGS. 1J-IN. This can result in substantially the same structure shown in FIG. 10.

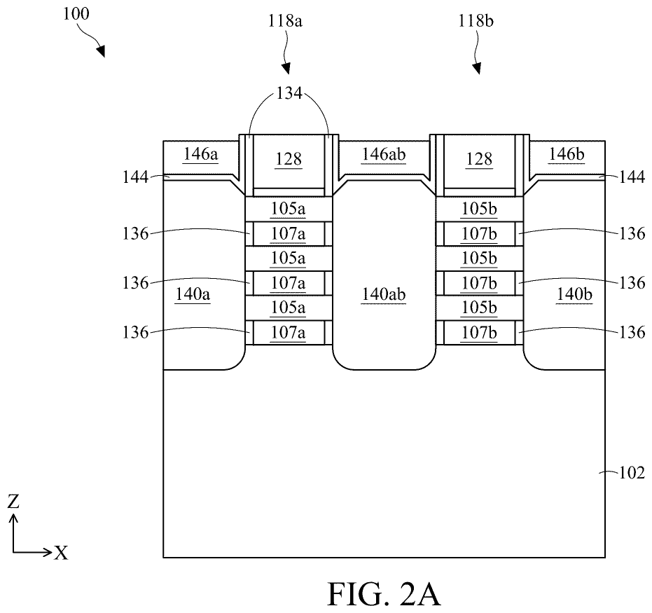

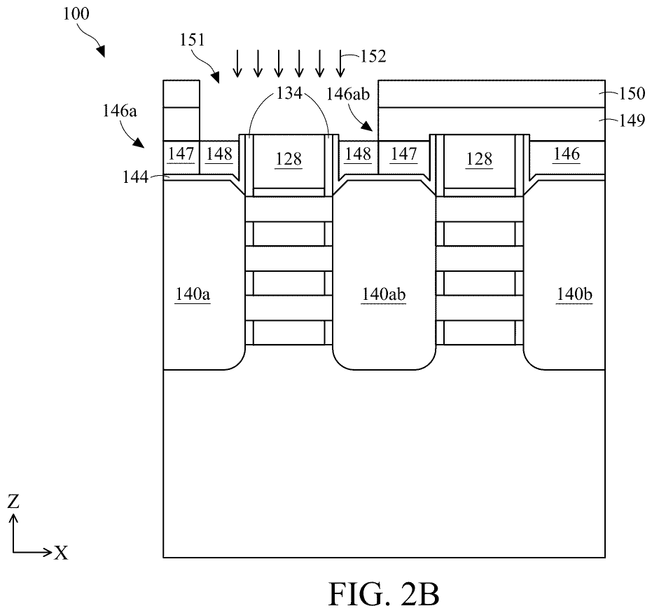

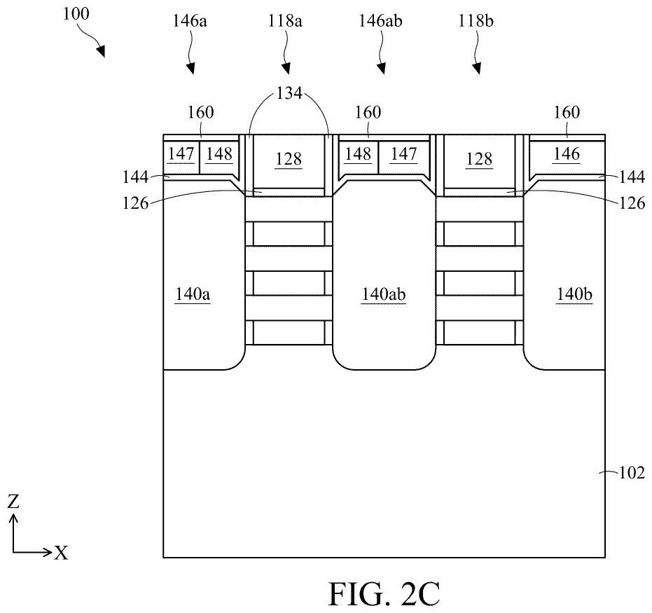

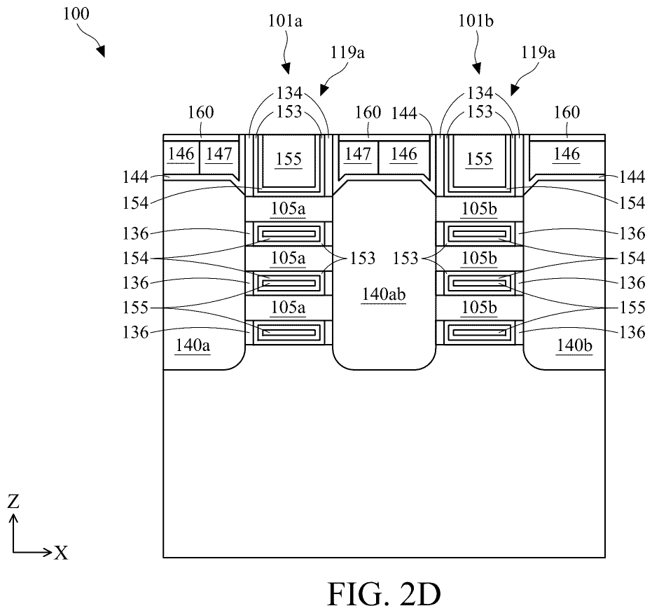

FIGS. 2A-2D are cross-sectional views of an integrated circuit 100 at various stages of processing, in accordance with some embodiments.

In FIG. 2A, the integrated circuit 100 is at a stage of processing substantially similar to that shown in FIG. 1I. However, in FIG. 2A, an etching process has been performed to recess the of the interlevel dielectric layer 146 with respect to the top of the sacrificial gate structures 118. The recessing process can include utilization of an etchant that selectively etches the material of the interlevel dielectric layer 146 with respect to the material of the CESL layer 144, the gate spacer layers 134, and the sacrificial gate layer 128. The result of this process is that the top of the interlevel dielectric layer 146 is recessed as shown in FIG. 2A.

The recessing process can be performed to facilitate implanting dopant species 152 into the exposed regions of the interlevel dielectric layer 146 with desired depths and concentrations. For example, in some cases the initial height (after CMP) of the interlevel dielectric layer 146 and above the source/drain regions 140 may be between 30 nm and 50 nm. The recessing process may be performed to reduce the height of the interlevel dielectric layer 146 to a dimension between 10 nm and 20 nm so that a subsequent dopant implantation process can result in a desired penetration depth and concentration of dopant species in exposed portions of the interlevel dielectric layer 146.

In FIG. 2B, the hard mask layer 149 and the photoresist layer 150 have been deposited and patterned to form openings 151, as described in relation to FIGS. 1J and 1K, in accordance with some embodiments. A dopant implantation process is performed as described in relation to FIG. 1L, in accordance with some embodiments. The result is that dopant species 152 are implanted into the exposed portions of the interlevel dielectric layers 146a and 146ab. This forms the portions 147 and 148 of different material compositions.

In some embodiments, the dopant species are also implanted into the upper portion of the sacrificial gate layer 128. In some embodiments, the dopant species do not substantially penetrate the sacrificial gate layer 128. In some embodiments, dopant species penetrate to only a very shallow depth of the gate 128. The dopant species can include Ge or N2. Accordingly, prior to removal, the sacrificial gate layer includes dopant species, in some embodiments. As the sacrificial gate layer 128 will be selectively removed in a subsequent etching process, if such dopant species would adversely affect the overall etchability of the sacrificial gate layer 128, a subsequent CMP process can be performed to remove the affected portion of the gate 128.

In FIG. 2C, the hard mask layer 149 and the photoresist layer 150 have been removed, in accordance with some embodiments. This leaves the portions 147 and 148 and the region 146b with top surfaces recessed relative to the top surface of the sacrificial gate structure 128.

In FIG. 2C, a protection layer 160 has been formed, in accordance with some embodiments. The protection layer 160 is a dielectric layer deposited in a conformal deposition process on top surfaces of the interlevel dielectric layer 146 and the sacrificial gate structures 118. After deposition of the protection layer 160, a CMP process can be performed to remove the protection layer 160 from the top surfaces of the sacrificial gate layer 128 and to make the top surface of the protection layer 160 substantially coplanar with the top surface of the sacrificial gate layer 128. In some embodiments, the dielectric protection layer is a low K dielectric layer. The dielectric protection layer 160 can include SiN, SiO, SiON, SiC, SiOC, SiOCN, or other suitable dielectric materials. The dielectric protection layer 160 can be deposited by CVD, ALD, PVD, or other suitable deposition processes.

In FIG. 2D, the sacrificial gate layer 128 and the sacrificial semiconductor nanostructures 107 have been removed, as described in relation to FIG. 1O, in accordance with some embodiments. The gate dielectric layer 153 and the gate metals 154 and 155 have been formed as described in relation to FIG. 1O, in accordance with some embodiments. The result is that the integrated circuit 100 of FIG. 2D have substantially the same structure as the integrated circuit 100 of FIG. 1O, except that the top surface of the interlevel dielectric layer 146 is recessed with respect to the top surface of the gate metal 155, and the dielectric protection layer 160 is present having a top surface substantially coplanar with the top surface of the gate metal 155.

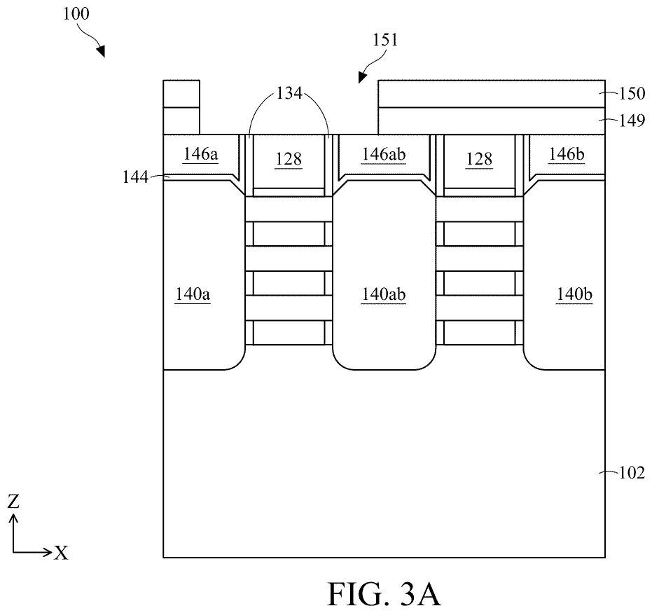

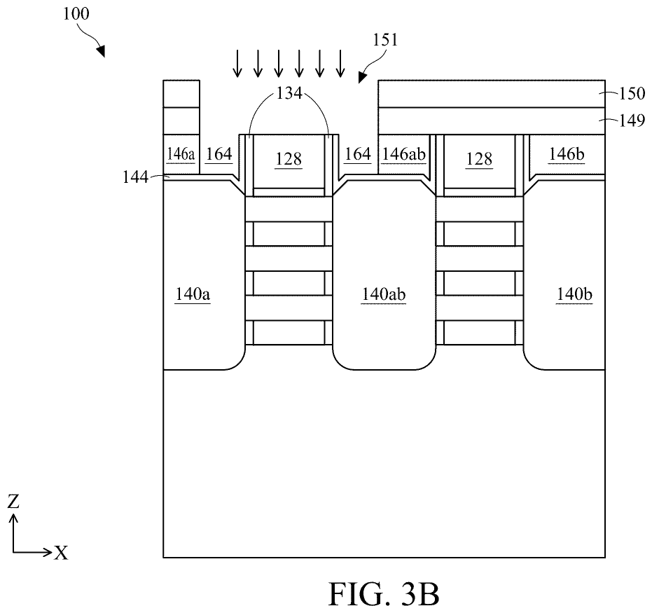

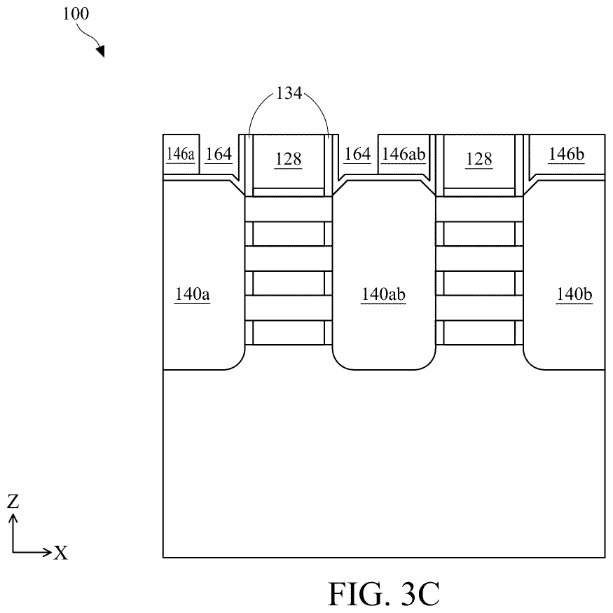

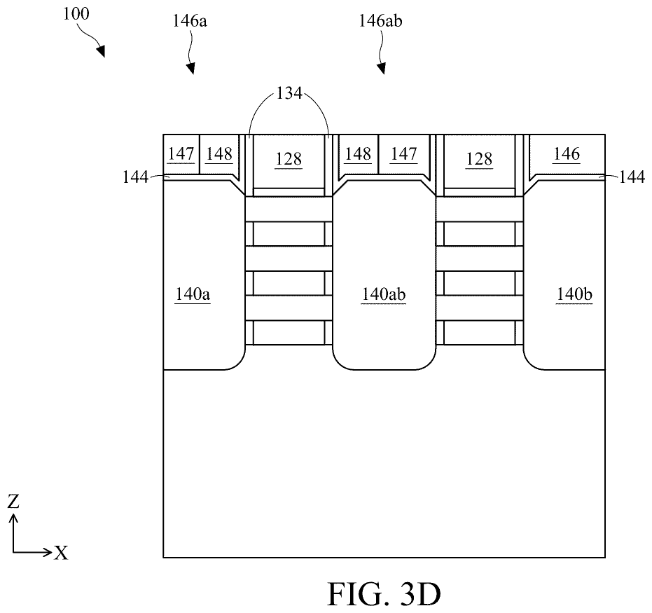

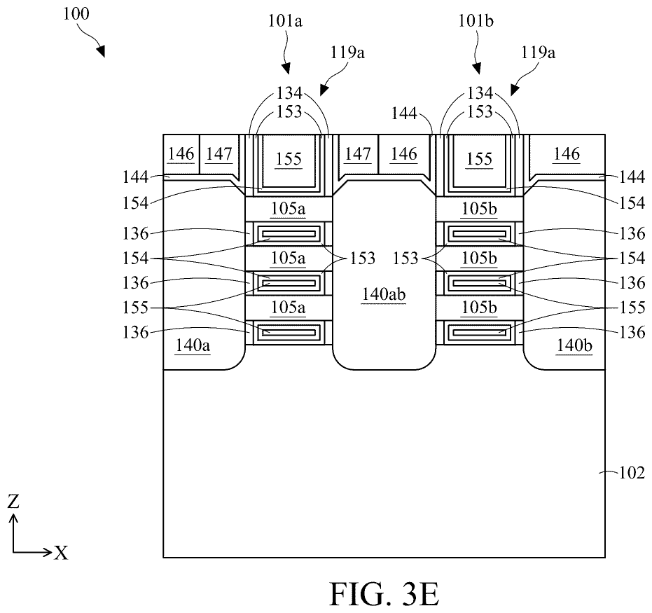

FIGS. 3A-3E are cross-sectional views of an integrated circuit 100, at various stages of processing, in accordance with some embodiments.

In FIG. 3A, the integrated circuit 100 is at a substantially similar stage of processing as the integrated circuit 100 of FIG. 1K, in accordance with some embodiments. In particular, the hard mask layer 149 and the photoresist layer 150 have been deposited and patterned to form openings 151. The openings 151 expose portions of the regions 146a and 146ab, while covering other portions of the regions 146a and 146ab and the entirety of the region 146b.

In FIG. 3B, an etching process has been performed in the presence of the hard mask layer 149, in accordance with some embodiments. The etching process is an anisotropic etching process that etches in the downward direction in some embodiments, the etching process is a reactive ion etching process that utilizes high-energy ions to etching the downward direction. Other types of anisotropic etching processes can be utilized without departing from the scope of the present disclosure. Furthermore, the etching process can selectively etch the material of the interlevel dielectric layer 146 with respect to the CESL layer 144, the gate spacer layers 134, and the sacrificial gate layer 128.

The result of the etching process is that the portions of the interlevel dielectric layer 146 that are exposed in the openings 151 are removed. This leaves gaps 164 in the interlevel dielectric layer 146 and exposes portions of the CESL layer 144.

In FIG. 3C, the hard mask layer 149 and the photoresist layer 150 have been removed, in accordance with some embodiments. This exposes the tops of the interlevel dielectric layer 146.

In FIG. 3D, a dielectric layer 148 has been deposited, in accordance with some embodiments. The dielectric layer 148 has a different material than the material of the interlevel dielectric layer 146. In an example in which the interlevel dielectric layer 146 includes silicon oxide, the dielectric layer 148 can include SiON, SiGeO, or other suitable dielectric materials having a different composition than the material of the interlevel dielectric layer 146.

After deposition of the dielectric layer 148, a CMP process is performed to remove portions of the dielectric layer from above the sacrificial gate layer 128. The result is that the interlevel dielectric layer 146a and 146b each include a first portion 147 and in the second portion 148 having different material compositions. The difference in material composition between the regions 147 and 148 provides the beneficial strain and other benefits described in relation to FIGS. 1M-1O.

In FIG. 3E, the sacrificial gate layer 128 and the sacrificial semiconductor nanostructures 107 have been removed, as described in relation to FIG. 1O, in accordance with some embodiments. The gate dielectric layer 153 and the gate metals 154 and 155 have been formed as described in relation to FIG. 1O, in accordance with some embodiments. The result is that the integrated circuit 100 of FIG. 3E has substantially the same structure as the integrated circuit 100 of FIG. 1O, except that the portions 148 of FIG. 3E may have slightly different composition than the portions 148 of FIG. 1O due to the portions 148 of FIG. 3E being formed by a deposition process rather than a dopant implantation process.

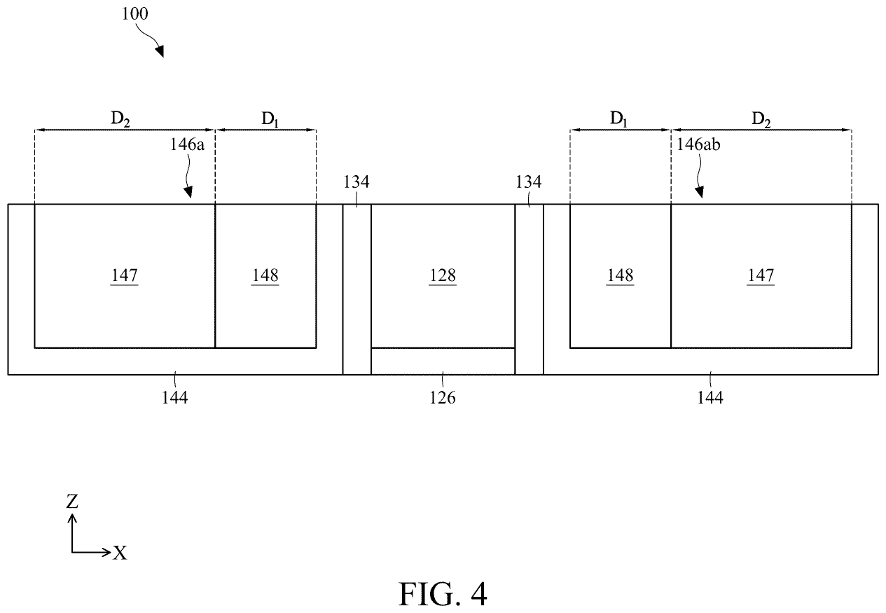

FIG. 4 is an enlarged cross-sectional view of a portion of an integrated circuit 100, in accordance with some embodiments. In particular, FIG. 4 illustrates the CESL layer 144, the interlevel dielectric layer 146a/146ab, the gate spacer layers 134, and the sacrificial gate layer 128, substantially at the stage of processing shown in FIG. 1N, in accordance with some embodiments. Alternatively, as described previously, the stage of processing shown can be substantially similar to the stage of processing shown in FIG. 1O, if the sacrificial gate layer 128 has been replaced by the gate metal 155 and other layers.

In FIG. 4, the interlevel dielectric layer portion 148 has a dimension D1 in the X direction. The interlevel dielectric layer portion 147 has a dimension D2 in the X direction. In some embodiments, the sum of D1 and D2 can have a value between 45 nm and 50 nm. D1/(D1+D2) can have a value between 10% and 100%. The concentration of dopants in the portions 148 can be between 1% and 50%, with the portion 147 having a smaller concentration or even no dopant concentration. Other dimensions and concentrations can be utilized without departing from the scope of the present disclosure. In some embodiments, the implantation process can induce out-gassing of oxygen from the exposed parts of the interlevel dielectric layer 146 and the gate spacer layer.

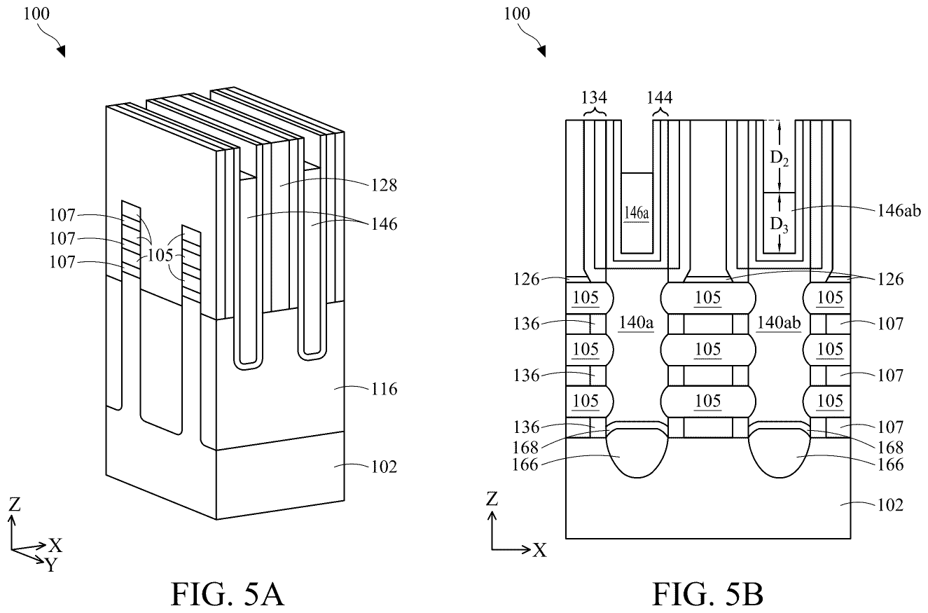

FIG. 5A is a perspective view of an integrated circuit 100, in accordance with some embodiments. The view of FIG. 5A corresponds to a stage of processing shown in FIG. 2A, in accordance with some embodiments. The perspective view of FIG. 5A illustrates the substrate, the trench isolation regions 116, the channels 105, the sacrificial semiconductor nanostructures 107, the gate spacer layers 134, the sacrificial gate layer 128, and the interlevel dielectric layer 146. The interlevel dielectric layer 146 has been recessed as described in relation to FIG. 2A. Subsequently, the masking and dopant implantation process and formation of the gate metal 155 may be performed as described in relation to FIGS. 1J-10.

FIG. 5B is a cross-sectional view of the integrated circuit 100, in accordance with some embodiments. The view of FIG. 5B corresponds to a stage of processing shown in FIG. 2A, in accordance with some embodiments. In FIG. 5B, the interlevel dielectric layer 146a is recessed to a different depth than the region 146b, in accordance with some embodiments. This can be accomplished via an additional masking and etching process that enables a deeper etching of the exposed area. In FIG. 5B, the region 146ab is recessed to a depth D2 relative to the top surface of the sacrificial gate layer 128. The remaining thickness of the region 146ab has a dimension D3. The dimension D2 is between 10 and 20 nm. The dimension D3 is between 10 and 20 nm. Other values for the dimensions D2 and D3 can be utilized without departing from the scope of the present disclosure. Subsequent to the stage of processing shown in FIG. 5B, the masking and dopant implantation process and formation of the gate metal 155 may be performed as described in relation to FIGS. 1J-10.

FIG. 5B illustrates a semiconductor layer 166 below the source/drain regions 140. In some embodiments, the semiconductor layer 166 is an intrinsic (undoped) semiconductor layer. The semiconductor layer 166 can include silicon, silicon germanium, or other suitable semiconductor materials.

FIG. 5B also illustrates a bottom dielectric structure 168 positioned between the semiconductor layer 166 and the source/drain regions 140. The bottom dielectric layer 168 can provide electrical isolation between the source/drain region 140 and the substrate 102. The bottom dielectric structure 168 can include SiN, SiO, SiON, SiCN, SIOCN, SiOC, or other suitable dielectric materials.

In FIG. 5B, the CESL layer 144 includes multiple dielectric layers rather than a single dielectric layer. The gate spacer layer 134 includes multiple gate spacer layers, rather than a single gate spacer layer. Other variations can be utilized without departing from the scope of the present disclosure.

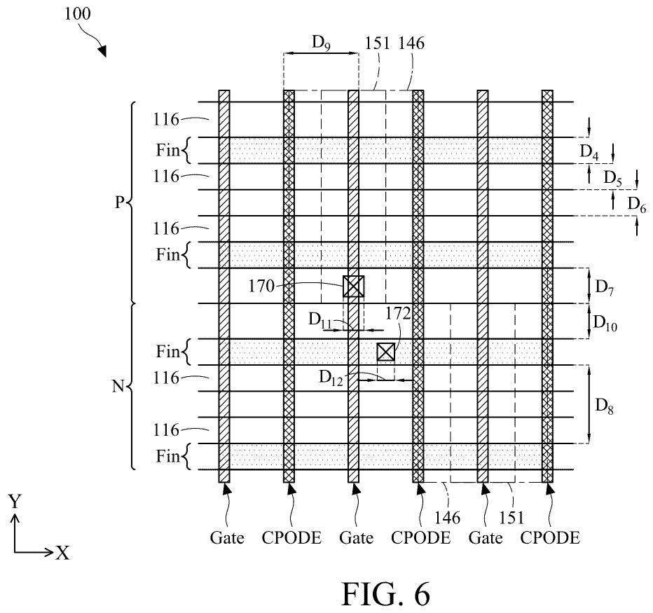

FIG. 6 is a top view layout of an integrated circuit 100, in accordance with some embodiments. The layout illustrates a P-region including two semiconductor fins 112 in which P-type transistors will be formed. The layout illustrates an N-region including two semiconductor fins 112 in which N-type transistors will be formed. The semiconductor fins extend in the X direction. The layout illustrates gate regions extending across the fins in the Y direction. The gate regions correspond to the locations at which the sacrificial gate structures 118 are initially formed in the eventually replaced with gate metals 155. The layout also illustrates continuous poly on diffusion edge (CPODE) structures extending in the Y direction. Each CPODE structure is between two gate structures. FIG. 6 illustrates the location of the trench isolation regions 116 adjacent to the fins extending in the Y direction. FIG. 6 illustrates the locations of the openings 151 (shown in dashed lines) through which the dopant implantation process described in relation to FIG. 1L will be performed. There is a dopant implantation window 151 in both the P-region and the N-region. In some embodiments, different gate metals will be deposited in the P-region than in the N-region. In FIG. 6, both of the source/drain regions of a transistor receive the dopant implantation process. In some embodiments, a cut metal gate structure can be formed extending in the Y direction between adjacent STI regions 116 in order to electrically isolation portions of gate structures extending in the Y direction.

FIG. 6 illustrates a single gate contact location 170 at which a conductive vias formed in contact with the gate region, in accordance with some embodiments. In practice, multiple gate contact locations 170 may be present. FIG. 6 also illustrates a source/drain contact region 172 at which a conductive via contacts a source/drain region. In practice, multiple source/drain contact regions 172 may be present.

In FIG. 6, the semiconductor fins have a width dimension D4 in the Y direction. The dimension D4 is between 15 nm and 25 nm. The trench isolation regions have a width dimension D5 in the Y direction. The dimension D5 is between 10 nm and 20 nm. The space between adjacent trench isolation regions has a width dimension D6 in the Y direction. The dimension D6 is between 15 nm and 20 nm. The P-type region has a width dimension D7 in the Y direction between the lower edge and the next semiconductor fin. The dimension D7 is between 20 nm and 30 nm. The dimension D8 between adjacent semiconductor fins is between 40 nm and 50 nm. The dimension D9 between a CPODE structure of the adjacent gate region is between 45 nm and 55 nm. The dimension D10 between the uppermost N-type semiconductor fin and the edge of the P-region is between 20 nm and 25 nm. The dimension D11 between the gate contact 170 and the adjacent semiconductor fin is between 4 nm and 7 nm. The width dimension D12 in the X direction of the source/drain contact region 172 and of the gate contact region 170 is between 10 nm and 15 nm. Other values for the dimensions can be utilized without departing from the scope of the present disclosure.

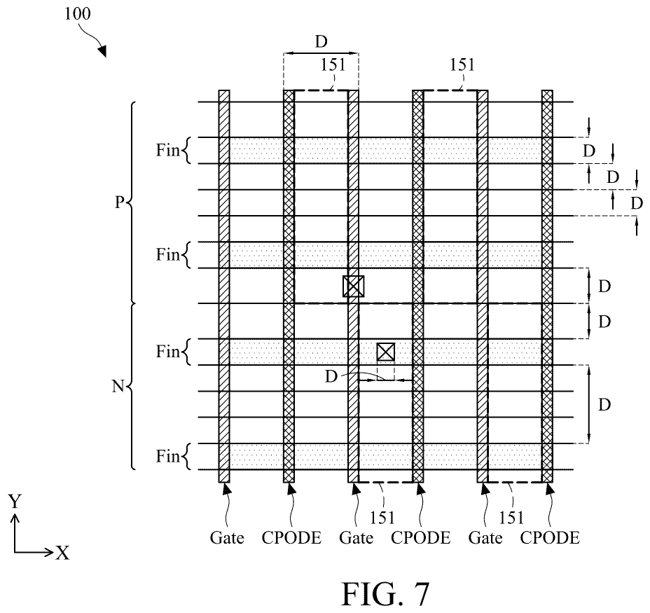

FIG. 7 is a top view of a layout of an integrated circuit 100, in accordance with some embodiments. The layout of FIG. 7 is substantially similar to the layout of FIG. 6, except that the dopant implantation windows 151 are different positions. There are two dopant implantation windows 151 in both the P-region and the N-region. In the Example of FIG. 7, only source regions or only drain regions receive the dopant implantation process rather than both source/drain regions of a transistor receiving the dopant implantation process as in FIG. 6.

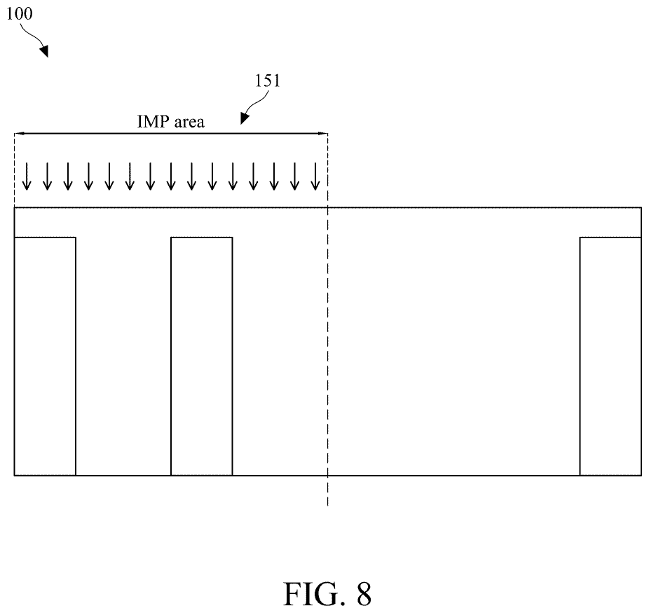

FIG. 8 is a top view of a layout of the integrated circuit 100, in accordance with some embodiments. The top view of the layout of FIG. 8 illustrates a dopant implantation window 151, in accordance with some embodiments. In some embodiments, the dopant implantation windows 151 can be present in both the P-region and the N-region or in only the P-region or the N-region. This can be utilized for devices that have different pitches between gate regions. In some embodiments, global implantation process can be performed for both the P-region and the N-region, followed by a partial implantation process from only the P-region or the N-region. In some embodiments, the global implantation process includes N2 dopants and the partial implantation process includes H2 dopants. In some embodiments, a partial implantation process can be performed only at the regions of selected devices. For example, a partial implantation process can be performed selectively at the locations of one or more of logic transistors, I/O transistors, bipolar transistors, electrostatic discharge transistors, SRAM transistors, or other regions. In some embodiments, the interlevel dielectric layer 146 is recessed, followed by regrowth of SiON or SiGeO.

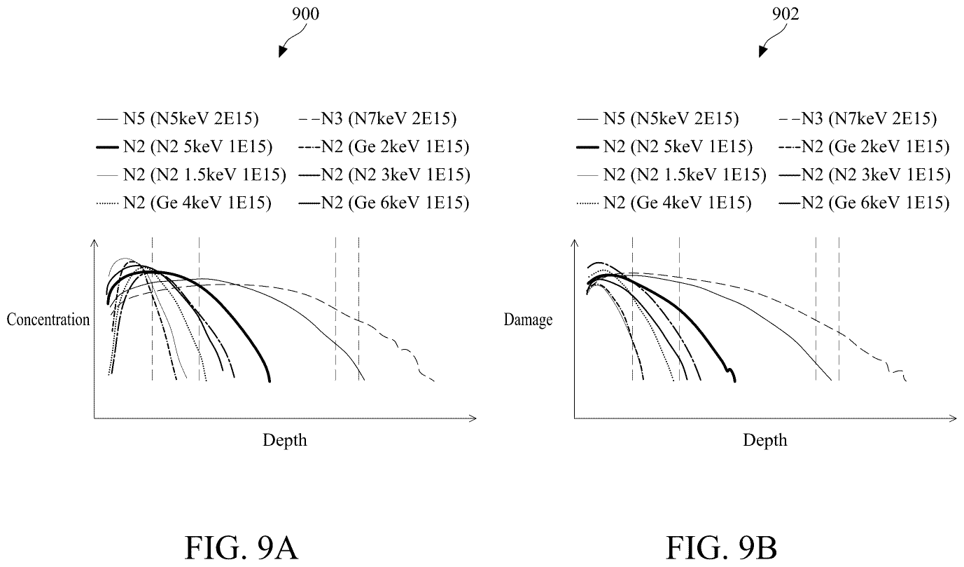

FIG. 9A is a graph 900 illustrating dopant concentration versus the depth of the interlevel dielectric layer 146, in accordance with some embodiments. The graph 900 illustrates a plurality of concentration distributions for various dopant species (N or Ge) and various implantation energies in keV, in accordance with some embodiments.

FIG. 9B is a graph 902 illustrating implantation damage in the interlevel dielectric layer 146 versus the depth of the interlevel dielectric layer 146, in accordance with some embodiments. The graph 902 also illustrates a plurality of distributions for various dopant species in the implantation energies, in accordance with some embodiments.

FIG. 10 is a flow diagram of a method 1000 for forming an integrated circuit, in accordance with some embodiments. The method 1000 can utilize the structures, processes, and systems described in relation to FIGS. 1-9B. At 1002, the method 1000 includes forming a mask layer over an interlevel dielectric layer. One example of a mask layer is the mask layer 149 of FIG. 1J. One example of an interlevel dielectric layer is the interlevel dielectric layer 146 of FIG. 1J. At 1004, the method 1000 includes patterning the mask layer so that the mask layer covers a first portion of the interlevel dielectric layer directly above a first source/drain region of a first transistor and exposes a second portion of the interlevel dielectric layer directly above the first source/drain region. One example of a first portion is the first portion 147 of FIG. 1L. One example of a second portion is the second portion 148 of FIG. 1L. One example of a first source/drain region is the first source/drain region 140a of FIG. 1L. One example of a first transistor is the first transistor 101a of FIG. 1O. At 1006, the method 1000 includes changing a material composition of the second portion relative to the first portion.

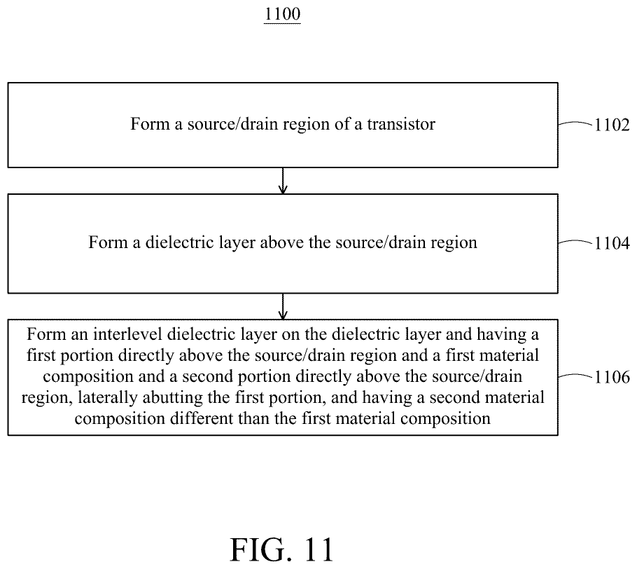

FIG. 11 is a flow diagram of a method 1100 for forming an integrated circuit, in accordance with some embodiments. The method 1100 can utilize the structures, processes, and systems described in relation to FIGS. 1-9B. At 1102, the method 1100 includes forming a source/drain region of a transistor. One example of a source/drain region is the source/drain region 140a of FIG. 1O. One example of a transistor is the transistor 101a of FIG. 1O. At 1104, the method 1000 includes forming a dielectric layer above the source/drain region. One example of a dielectric layer is the dielectric layer 144 of FIG. 1O. At 1106, the method 1000 includes forming an interlevel dielectric layer on the dielectric layer and having a first portion directly above the source/drain region and having a first material composition and a second portion directly above the source/drain region, laterally abutting the first portion, and having a second material composition different than the first material composition. One example of an interlevel dielectric layer is the interlevel dielectric layer 146 of FIG. 1O. One example of a first portion is the first portion 147 of FIG. 1O. One example of a second portion is the second portion 148 of FIG. 1O.

Embodiments of the disclosure provide an integrated circuit including an interlevel dielectric layer formed above a source/drain region of a transistor. During processing, the interlevel dielectric layer is altered so that a first portion of the interlevel dielectric layer has a first composition and a second portion of the interlevel dielectric layer has a second composition different from the first composition. In some embodiments, the difference in composition is accomplished by patterning a mask above the interlevel dielectric layer such that the first portion of the interlevel dielectric layer is covered by the mask while the second portion of the interlevel dielectric layer is exposed by the mask. In some embodiments, an ion implantation process is then performed to change the composition of the exposed second portion of the interlevel dielectric layer. In some embodiments, the second portion of the interlevel dielectric layer is removed and replaced with a dielectric material that is different than the remaining dielectric material of the first portion of the interlevel dielectric layer. This difference in composition imparts a beneficial strain to the source/drain region of the transistor. This results in improved performance of the transistor, for example by improving the mobility of charge carriers in the source/drain region. Furthermore, undesired oxygen concentrations in both N-type and P-type regions can be reduced, resulting in improvement in both N-type and P-type transistors. Additionally, the capacitance equivalent thickness is also reduced.

In some embodiments, a method includes forming a mask layer over an interlevel dielectric layer and patterning the mask layer so that the mask layer covers a first portion of the interlevel dielectric layer above a first source/drain region of a first transistor and exposes a second portion of the interlevel dielectric layer above the first source/drain region. The method includes changing a material composition of the second portion relative to the first portion.

In some embodiments, an integrated circuit includes a first transistor including a first source/drain region and a gate structure and an interlevel dielectric layer. The interlevel dielectric layer includes a first portion above the first source/drain region and having a first material composition and a second portion above the first source/drain region, laterally abutting the first portion, and having a second material composition different than the first material composition.

In some embodiments, a method includes forming a source/drain region of a transistor and forming a dielectric layer above the source/drain region. The method incudes forming an interlevel dielectric layer on the dielectric layer and having a first portion above the source/drain region and having a first material composition and a second portion above the source/drain region, laterally abutting the first portion, and having a second material composition different than the first material composition.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a mask layer over an interlevel dielectric layer;
patterning the mask layer so that the mask layer covers a first portion of the interlevel dielectric layer above a first source/drain region of a first transistor and exposes a second portion of the interlevel dielectric layer above the first source/drain region; and
changing a material composition of the second portion relative to the first portion.

2. The method of claim 1, wherein changing the material composition of the second portion relative to the first portion includes performing a dopant implantation process on the second portion in the presence of the mask layer.

3. The method of claim 2, wherein changing the material composition of the second portion relative to the first portion includes performing a thermal annealing process after the dopant implantation process.

4. The method of claim 2, comprising:
recessing a top surface of the interlevel dielectric layer relative to a top surface of a gate spacer layer;
forming the mask layer after recessing the top surface; and
depositing a dielectric protection layer on both the first portion and the second portion after performing the dopant implantation process.

5. The method of claim 4, comprising planarizing a top surface of the dielectric protection layer and the top surface of the gate spacer layer by performing a chemical mechanical planarization process.

6. The method of claim 1, wherein changing the material composition of the second portion relative to the first portion includes:
removing the second portion in the presence of the mask; and
redepositing the second portion by depositing a dielectric material different than a dielectric material of the first portion.

7. The method of claim 1, comprising depositing a gate metal of the first transistor after changing the material composition of the second portion relative to the first portion.

8. The method of claim 1, comprising changing the material composition of the second portion relative to the first portion after depositing a gate metal of the first transistor.

9. The method of claim 1, wherein after patterning the mask layer, the mask layer covers an entirety of the interlevel dielectric layer directly above a second source/drain region of the first transistor.

10. The method of claim 1, wherein after patterning the mask layer, the mask layer covers an entirety of the interlevel dielectric layer directly above a second source/drain region of a second transistor adjacent to the first transistor.

11. The method of claim 1, wherein after patterning the mask layer, the mask layer covers a third portion of the interlevel dielectric layer directly above a second source/drain region of the first transistor and exposes a fourth portion of the interlevel dielectric layer directly above the second portion of the second source/drain region, the method comprising changing a material composition of the fourth portion relative to the third portion.

12. The method of claim 1, wherein changing a material composition of the second portion relative to the first portion increases a charge carrier mobility in the first source/drain region by imparting a strain to the first source/drain region.

13. An integrated circuit, comprising:
a first transistor including a first source/drain region and a gate structure; and
an interlevel dielectric layer including:
a first portion above the first source/drain region and having a first material composition; and
a second portion above the first source/drain region, laterally abutting the first portion, and having a second material composition different than the first material composition.

14. The integrated circuit of claim 13, wherein the first and second portions have a same vertical thickness.

15. The integrated circuit of claim 13, comprising a dielectric protection layer on a top surface of the first portion, on a top surface of the second portion, and having a top surface substantially coplanar with a top surface of the gate structure.

16. The integrated circuit of claim 13, wherein a top surface of the first portion, a top surface of the second portion, and a top surface of the gate structure are substantially coplanar.

17. The integrated circuit of claim 13, comprising a second transistor including a second source/drain region, wherein an entirety of the interlevel dielectric layer that is directly above the second source/drain region has the first material composition.

18. A method, comprising:
forming a source/drain region of a transistor;
forming a dielectric layer above the source/drain region; and
forming an interlevel dielectric layer on the dielectric layer and having a first portion directly above the source/drain region and having a first material composition and a second portion directly above the source/drain region, laterally abutting the first portion, and having a second material composition different than the first material composition.

19. The method of claim 18, wherein the dielectric layer is a contact etch stop layer having a thickness less than a thickness of the interlevel dielectric layer.

20. The method of claim 18, wherein the first material composition is silicon oxide and the second material composition is silicon germanium oxide.
